(19) United States
(12) Patent Application Publication
(10) Pub. No.: US 2008/0090403 A1
(43) Pub. Date: Apr. 17, 2008

(54) APPARATUS AND METHOD FORMING A CONTACT TO SILICIDE AND A CONTACT TO A CONTACT

(75) Inventors: Rudolf Schlangen, Berlin (DE); Uwe Jurgen Kerst, Berlin (DE); Peter Sadewater, Berlin (DE); Mark A. Thompson, Austin, TX (US)

Correspondence Address: SUGHRUE MION, PLLC, 2100 Pennsylvania Avenue, N.W., Washington, DC, 20037, US

(73) Assignee: Credence Systems Corporation, Milpitas, CA (US)

(21) Appl. No.: 11/537,894

(22) Filed: Oct. 2, 2006

(51) Int. Cl. H01L 21/44

(52) U.S. Cl. 438/599; 438/597

(57) ABSTRACT

An apparatus and method for forming a contact to silicide through an active diffusion region, a contact to a contact through an active diffusion region, and a contact to a polysilicon structure through a shallow trench isolation region to create a conductive connection with a circuit node of interest. In one embodiment, an opening through the active diffusion region to an associated silicide layer is used to form the conductive connection. In another embodiment, an opening through the active diffusion region to an associated contact is used to form the conductive connection. In yet another embodiment, an opening through a shallow trench isolation region to a polysilicon structure is used to form the conductive connection.

### FIELD OF THE INVENTION

Aspects of the present invention relate generally to the field of circuit editing using a charged particle tool, and more particularly to an apparatus and method for contacting a silicide layer to form a low ohmic contact with an active structure.

### BACKGROUND

A newly-designed integrated circuit (“IC”) is typically fabricated over a process of several weeks, involving preparation of silicon substrate wafers, generation of masks, doping of the silicon substrate, deposition of metal layers, and so on. The IC typically has various individual electronic components, such as resistors, capacitors, diodes, and transistors. The metal layers, which may be aluminum, copper, or other conductive material, provide the interconnection mesh between the various individual electronic components to form integrated electrical circuits. Vias formed of electrically conductive material often provide communication pathways between various metal layers. Contacts provide communication links between metal layer and individual electronic components.

Unfortunately, a new IC of any complexity rarely works as expected when first fabricated. Normally, some defects in the operation of the IC are discovered during testing. Also, some functions of the IC may operate properly under limited conditions, but fail when operated across a full range of temperature and voltage in which the IC is expected to perform. Once the IC has been tested, the designer may change the design, initiate the manufacture of a second prototype IC via the lengthy process described above, and then test the new IC once again. However, no guarantee exists that the design changes will correct the problems previously encountered, or that all of the problems in the previous version of the IC have been discovered.

Charged particle beam systems, such as focused ion beam (“FIB”) systems, have found many applications in various areas of science and industry. Particularly in the semiconductor industry, FIB systems are used for integrated circuit probe point creation, failure analysis, and numerous other applications. Moreover, FIB systems may be used to edit a circuit (“circuit editing”) to test design charges and thereby avoid some or all of the expense and time of testing design changes through fabrication. A FIB tool typically includes a particle beam production column designed to focus an ion beam onto the IC at the place intended for the desired intervention. Such a column typically comprises a source of ions, such as Ga+ (Gallium), produced from liquid metal. The Ga+ is used to form the ion beam, which is focused on the IC by a focusing device comprising a certain number of electrodes operating at determined potentials so as to form an electrostatic lens system. Other types of charged particle beam systems deploy other arrangements to produce charged particle beams having a desired degree of focus.

As mentioned above, IC manufacturers sometimes employ a FIB system to edit the prototype IC, thereby altering the connections and other electronic structures of the IC. Circuit editing involves employing an ion beam to remove and deposit material in an IC with precision. Removal of material, or milling, may be achieved through a process sometimes referred to as ion sputtering. Addition or deposition of material, such as a conductor, may be achieved through a process sometimes referred to as ion-induced deposition. Through removal and deposit of material, electrical connections may be severed or added, which allows designers to implement and test design modifications without repeating the wafer fabrication process.

One particular problem in conventional circuit editing involves forming a connection with semiconductor electronic components, such as a connection with the n-diffusion or p-diffusion regions of a semiconductor transistor structure. Platinum or Tungsten based conductors are typically employed to form a conductive path during circuit editing procedures. In conventional FIB-based deposition processes, these conductors form good contacts with metal layers, but form poor, typically rectifying contacts, with semiconductor electronic components. This problem is alleviated to some extent when circuit editing is performed through the top side of a chip, i.e., through the metal layers, where metal to semiconductor connections are already available to form conductive contacts. During the IC fabrication process, the contact directly to the semiconductor material is enabled through an anneal, which forms silicide that couples the semiconductor material to the metal conductor. Silicide is desired because it provides a good electrical contact, not rectifying but ohmic, between the semiconductor structure and metal interconnections.

Due to the increasing density of metal interconnections and number of metal layers, FIB based circuit editing through the topside of an IC is increasingly difficult. It is often the case that FIB milling to define access holes to reach a deep metal layer in the semiconductor structure would damage or destroy other structures or layers along the way. To avoid this, increasingly, FIB circuit editing is performed through the backside silicon substrate of the chip. While going through the backside allows a virtually unimpeded connectivity to the desired locations, there is no preexisting metal to which a conductor may be attached. A conventional approach for creating an ohmic contact between a probe or conductor or semiconductor structure during fabrication is to anneal the contact area; however, conventional fabrication annealing is not feasible if the IC has already been fabricated because the anneal temperature would damage or destroy the temperature-sensitive components.

One approach to connecting to a circuit node involves milling an access hole through an electrically unused area of the chip such as a shallow trench isolation (“STI”) region separating active regions of adjacent devices. However, as chips become more dense, direct access to a target metal line through a shallow trench isolation region will most likely require high aspect ratio access holes and therefore increased via resistance or might even be fully blocked by a polysilicon line or gate extension that lies between the STI and the targeted metal line.

Thus, the efficiency and potential of FIB-based circuit editing techniques are limited by the difficulty or impossibility in forming contacts with various semiconductor structures using conventional post-fabrication techniques.

### SUMMARY

One aspect of the present invention involves a method for forming a conductive connection with an active node of a semiconductor structure by opening a contact hole through an active diffusion region to a silicide layer associated with the active diffusion region. The method further involves depositing a conductive material in the contact hole to form a conductive connection to the silicide layer.

Another aspect of the present invention involves a method for forming a conductive connection with an active node of a semiconductor structure by opening a contact hole through an active diffusion region to a contact associated with the active diffusion region. The method further involves depositing a conductive material in the contact hole to form a conductive connection to the contact.

Yet another aspect of the present invention involves a method for forming a conductive connection with an active node of a semiconductor structure by opening a contact hole through a shallow trench isolation region to a polysilicon gate contact area or other polysilicon structure. The method further involves depositing a conductive material in the contact hole to form a conductive connection to the polysilicon gate contact area or other polysilicon structure.

### BRIEF DESCRIPTION OF THE DRAWINGS

FIG. 1 is a flowchart illustrating one method of forming a contact to silicide and a contact to contact, in accordance with one embodiment of the present invention.

FIG. 2 is a block diagram of a system for performing circuit edit operations according to certain embodiments of the present invention.

FIG. 3 is a schematic section view of an integrated circuit illustrating the process flow of a backside circuit edit.

FIG. 4 is a schematic section view of an integrated circuit illustrating different methods of obtaining ohmic contacts to a circuit node of interest.

FIG. 5 is a section view of an integrated circuit illustrating the current flow through a device after a conductive connection to a contact has been established by milling through the highly doped area of a source/drain implant.

FIG. 6 is a schematic section view of an integrated circuit illustrating another method of obtaining an ohmic contact to a silicide region of a circuit node of interest.

FIG. 6A depicts the doping profiles of the diffusion regions of the schematic section view of the integrated circuit of FIG. 6.

FIG. 7 shows a portion of an integrated circuit layout illustrating the layout of a 3-way NAND gate and possible areas for focused ion beam contacts to silicide.

FIG. 8 is an image of an angled cut through a STI surrounded n+/CoSi interface region.

FIG. 9 illustrates the brightness increase observed using an endpoint detection tool during the perpendicular cut through the materials stack comprised of the n+ diffusion region and terminating in the CoSi interface region of FIG. 7.

FIG. 10 is a SEM image depicting a cross-sectional view through a 0.5 μm-wide FIB created contact to silicide.

FIG. 11 depicts the measurement setup used to determine the resistance of CtC and CtS structures.

FIG. 12 shows the measured I-V curve of a 2 μm² FIB created contact to silicide.

FIG. 13 illustrates the layout of a ring oscillator showing the target circuit edit area and a FIB picture of the target area opened down to the STI level.

FIG. 14 depicts the initial steps of a FIB circuit edit operation on one of the 3-gate n-FETs of the ring oscillator of FIG. 13 showing the STI area, the n-FET active area and a cut down to the CoSi layer.

FIG. 15 depicts additional steps of the FIB circuit edit operation on the ring oscillator of FIG. 13 showing the contact to silicide opening filled with FIB deposited platinum and the purposeful destruction of two of the n-FETs by milling down until the polysilicon gates and contacts appeared.

FIG. 16 is a schematic section view of a portion of the ring oscillator of FIG. 13 after completion of the FIB circuit edit to create a contact to silicide illustrating the resulting signal path around the FIB removed n-FET area.

FIG. 17 depicts the ring oscillator frequency during the contact to silicide FIB circuit edit performed on the ring oscillator of FIG. 13.

FIG. 18 depicts the single FET test structure used to evaluate the contact properties of the contact to contact method, in accordance with one embodiment of the present invention.

FIG. 19 shows a cross section of a portion of a ring oscillator after circuit edit illustrating the signal flow around the FIB removed area using a FIB created contact to contact.

FIG. 20 depicts steps of a circuit edit on the portion of the ring oscillator of FIG. 19 showing the contact hole opened to form a conductive connection to the output of a NAND inverter using a FIB created contact to contact, the contact hole opened to the metal line connected to the input of a NAND inverter located three inverters further along the ring oscillator, and the location of the FIB deposited platinum trace to reestablish the signal path around the removed NAND inverters.

FIG. 21 depicts an enlarged view of the FIB created contact to contact of FIG. 20.

FIG. 22 depicts an enlarged view of the FIB created contact to metal layer of FIG. 20.

FIG. 23 shows the ring oscillator output frequency during the circuit edit of the portion of the ring oscillator shown in FIG. 19.

FIG. 24 is a schematic section view of an integrated circuit illustrating various methods of obtaining ohmic contacts to a circuit node of interest.

FIG. 25 shows a portion of an integrated circuit layout illustrating the layout of a 3-way NAND gate and possible areas for focused ion beam contacts to polysilicon structures.

FIG. 26 illustrates the initial peak in brightness observed using an endpoint detection tool as the STI layer is milled through to expose the STI/polysilicon interface which is followed by a sudden decrease in brightness as the polysilicon structure of FIG. 24 is exposed.

### DETAILED DESCRIPTION

Aspects of the present invention involve an apparatus and method for forming conductive contacts with active nodes of a semiconductor structure in a fabricated integrated circuit (“IC”) when backside circuit edits are performed using a charged particle beam tool such as a focused ion beam (“FIB”) tool. The conductive contacts may be used to form connections to circuit nodes of interest. One aspect of the invention involves forming a conductive connection to a silicide region of an active node of the semiconductor structure (“CtS”).

Another aspect of the invention involves forming a conductive connection to a contact (“CtC”) through an active node of the semiconductor structure. Such contacts typically form a connection between a metal interconnect and the active node. These contacts may include, but are not limited to, tungsten plugs. Yet another aspect of the invention involves forming a conductive connection through a shallow trench isolation region to a polysilicon gate or other polysilicon structure of the semiconductor structure (“CtP”). As used herein, the term “semiconductor structure” refers to any active or passive circuit structure formed from appropriate doping of a semiconductor base material such as silicon, silicon germanium, germanium, and gallium arsenide. Some examples of semiconductor structures include transistors and diodes formed in a complementary metal oxide semiconductor (“CMOS”) and/or bipolar arrangements with appropriate diffusions.

The conductive connections formed during circuit edit may be used to facilitate the debugging and testing of a newly fabricated IC. During the debug and test of the IC, an open signal path or defective device may be found that prevents a portion of the IC from properly functioning. Circuit edits employing conductive connections may be used to repair the open signal path, to bypass the defective device, or to substitute a spare device in place of a defective device, thereby restoring functionality to that portion of the IC. Thus, the debugging and testing of the IC can continue on without having to fabricate another IC to repair the defect, a costly and lengthy process.

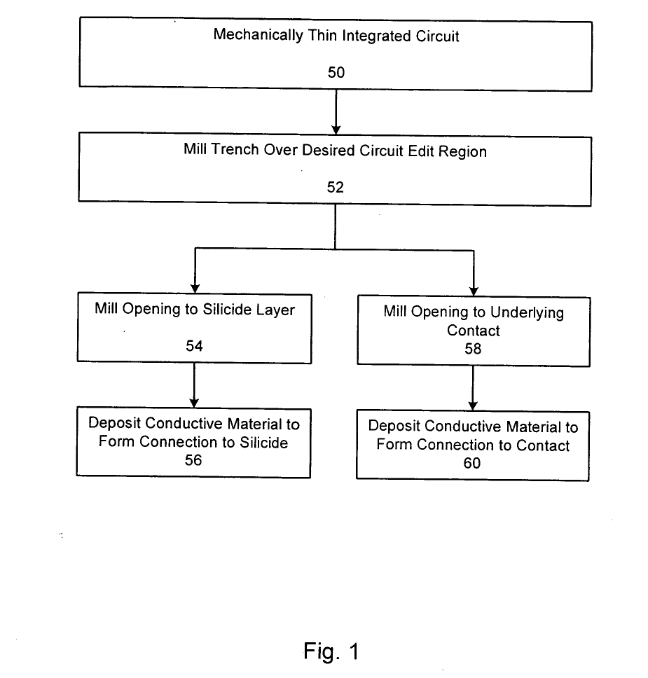

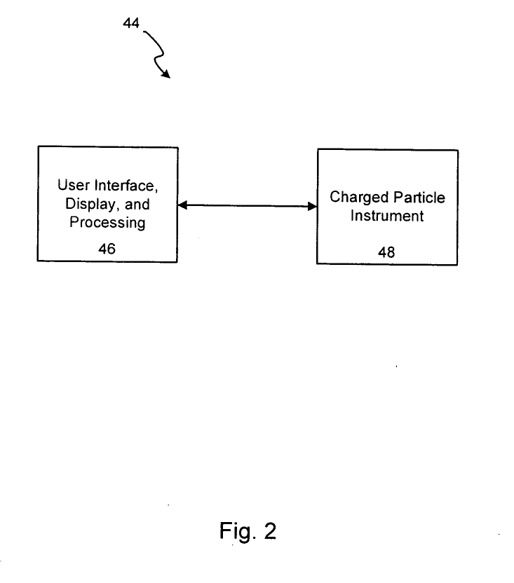

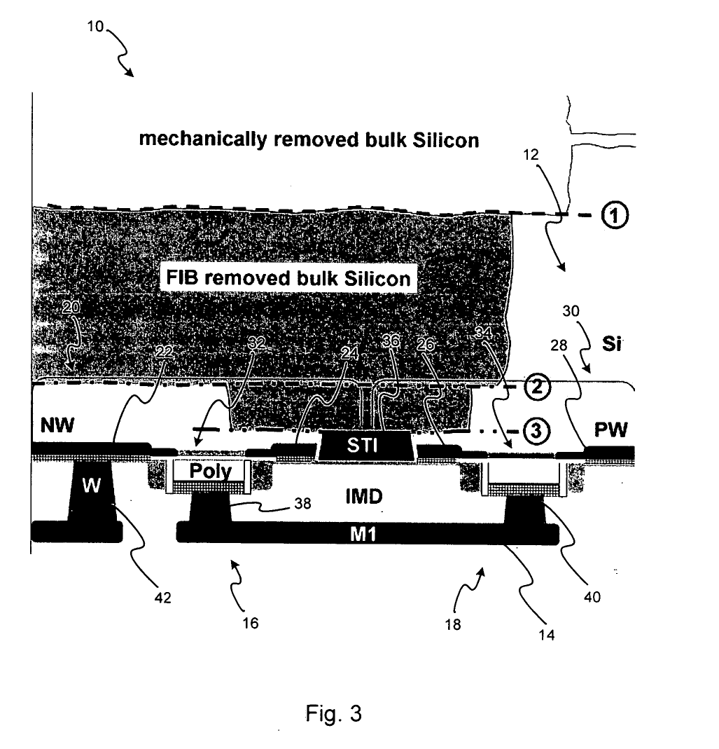

The operations of one method conforming to the present invention are shown in the flowchart of FIG. 1 with reference to the portion of an IC shown in FIG. 3. The operations may be performed by a circuit editing system 44 as depicted in FIG. 2. The circuit editing system includes a user interface, display and processing module 46 and a charged particle instrument 48, such as a focused ion beam tool, which are communicatively connected to each other.

The IC of FIG. 3 and others herein are CMOS based ICs; however, the methods and apparatus conforming to the present invention discussed herein may be applied to bipolar and other ICs as well. The backside of the IC is shown at the top of FIG. 3, with the active structures, metal lines, etc., at the bottom of FIG. 3. An integrated circuit 10 includes a semiconductor substrate 12 with transistors and other semiconductor structures formed at the top of the substrate through oxidation, diffusion, implantation and other methods. Above the substrate, are one or more metal layers 14 containing the various metal interconnects that provide the communication pathways between the semiconductor structures of the IC.

Referring to FIG. 3, a schematic diagram of a section of an example IC is shown. FIG. 3 also shows some portions of the substrate removed by the above backside edit processing procedure. In the example IC, a p-type MOS field effect transistor (“P-FET”) 16 and a n-type MOS field effect transistor (“N-FET”) 18 are shown. The P-FET transistor includes an n-well 20 and p-diffusion regions (drain 24 and source 22). In contrast, the N-FET transistor includes n-diffusion regions (drain 26 and source 28) and a p-well 30 (which may be the p-type substrate 12). Each transistor arrangement includes a self-aligned polysilicon gate (32, 34) between the respective source and drain. Insulating material isolates the active diffusion areas of the two FETs. Here, a shallow trench isolation (“STI”) region 36 forms an insulator (SiO₂) between the two transistors. The two gates are connected via metal layer M1 and Tungsten plugs 38, 40. A tungsten plug 42 may also be used to connect a source/drain region to metal layer M1.

Referring to FIG. 1, to process an IC in accordance with a method conforming to the present invention, the substrate is thinned (operation 50). Substrate thinning, a process that removes a portion of the substrate may be done by a thinning technique referred to as lapping. It is also possible to use other thinning or polishing techniques, such as a chemical mechanical polishing and planarization technique, a FIB tool with a gas etchant (e.g., XeF₂), other charge particle tools, and electron beam or laser activated chemical etch options, to thin all or only target portions of the substrate. Typically, the entire substrate of the IC is uniformly thinned before further processing as indicated by Line 1 of FIG. 3, but it is not necessary to thin the entire substrate.

Next, a charged particle beam tool (e.g., focused ion beam tool, e-beam tool, etc.) is employed to form one or more trenches, denoted by Line 2 of FIG. 3, in the substrate below the target structure or structures where circuit editing is to take place (operation 52). The desired trench depth may be established by endpointing on the N-Well to halt the milling process. The term “endpointing” refers to determining when to stop the milling operation at a certain depth and may be performed by monitoring some signal from the operation that is dependent upon the composition of the material being milled.

The trench(es) is (are) intended to additionally thin the substrate so that the target semiconductor structures or other portions of the IC become detectable. As used herein, the term “circuit edits” broadly refers to any type of charged particle beam, laser beam, or other beam-based, mechanical, or other procedure that modifies an IC in any way, including cutting or removing any feature of an integrated circuit as well as depositing material, such as depositing a conductor or trace to form an electrical connection or pathway.

After definition of the local trench, one or more shallow trench isolation (“STI”) alignment windows may be milled in the trench floor over the target structures to further thin selected portions of the substrate and expose the bottom of the STI regions. In one embodiment, the STI alignment opening may be done with a FIB using metal etch chemistry and a beam current of approximately 3 to 5 pA/μm². The bottom of the STI regions may be used as navigation guides to locate the circuit features of interest.

Next a charged particle beam tool may be used to mill one or more node access holes to the silicide regions (operation 54) of the targeted active nodes. The node access holes to silicide regions are generally performed with reduced beam current and are placed as far away from adjacent transistor gates as possible to avoid damage to the edited device. In one embodiment, the node access holes may be milled with a FIB using an unassisted etch and a beam current of approximately 3 to 5 pA/μm².

Once the node access holes have been milled, a charged particle beam tool may be used to deposit a conductive material in the node access holes to form conductive traces to the silicide regions and corresponding active nodes (operation 56). In one embodiment, the conductive traces may be formed using a FIB with a beam current of approximately 10 pA/μm² to deposit a platinum conductor. These conductive traces may also be used to connect one circuit edit structure to another one.

During a circuit edit, access to lower metal layer lines and polysilicon lines from the front side of the IC can be difficult using a charged particle beam tool and may result in gate failure if the circuit edit is not precisely controlled. In some instances, access from the front side to the lower metal lines and poly lines may be limited by an intervening metal line, polysilicon gate or some other structure. Backside circuit edits may overcome these limitations.

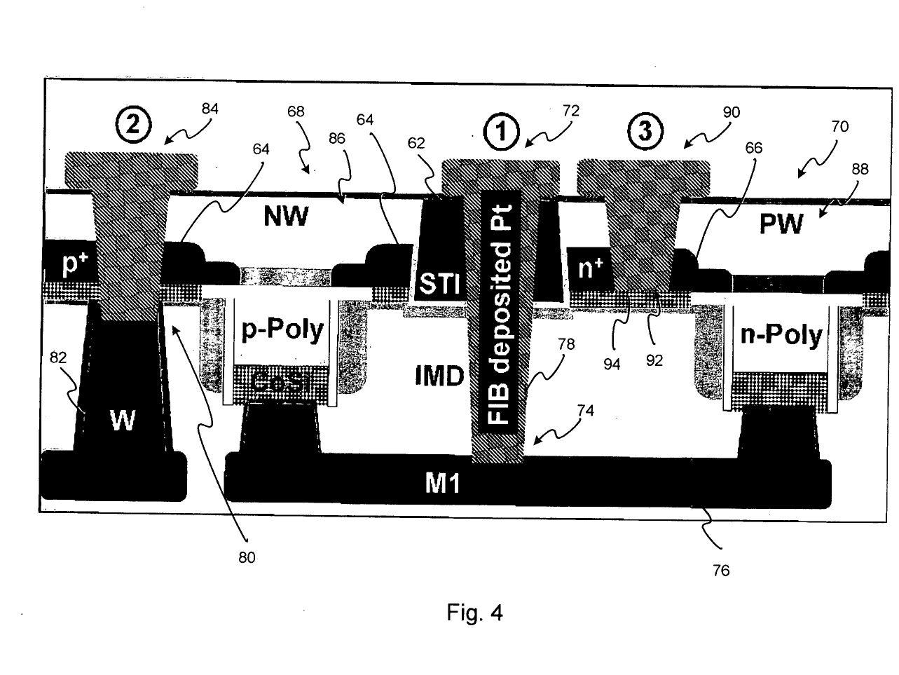

FIG. 4 depicts various methods for creating a conductive connection to a circuit node through the floor of the STI alignment window using a FIB tool. The classical way of connecting to a circuit node involves using the FIB tool to drill a high aspect ratio hole through the STI block 62 separating active diffusion regions 64, 66 of two FETs 68, 70 to form a conduit for making a connection 72 with the desired metal line 76. The term “aspect ratio” refers to the ratio of hole depth to hole diameter. Milling through the STI does not harm the functionality of the IC. Platinum 78, or other conductive material can then be deposited in the access hole using the FIB tool to create an ohmic contact 74 with the metal line 76. However, as chip densities continue to increase, access to the desired metal line through the STI may be blocked by an intervening poly silicon line or gate extension. Also as circuit densities continue to increase, the aspect ratio of the access hole may preclude being able to endpoint at the desired depth or may result in high resistance connections.

The above limitations of contacting a metal line through the STI may be overcome by creating a conductive connection 80 to a contact 82 (“CtC” 84). With this method, a conductive connection to a contact 82, including but not limited to a tungsten plug, can be established by using the FIB tool to drill through the N-Well 86 and the highly doped p+ source/drain implant region 64 of p-FET 68, endpointing on the contact 82, in this instance a tungsten plug. The FIB tool is then used to deposit a conductive material such as platinum, in the milled hole to form the conductive connection with the tungsten plug 82. Even though the platinum deposition passes through the N-well and also the p+ diffusion area, no insulating material is needed to prevent a short circuit between the highly doped p+ diffusion 64 and N-well 86 because the deposited conductor only forms a very poor electrical contact (neither rectifying or ohmic) to the low doped well material which can generally be neglected. A conductive connection to a contact of a n-FET may be established by a similar procedure, except that the FIB tool drills through the P-Well and n+ diffusion region of the n-FET to reach the contact.

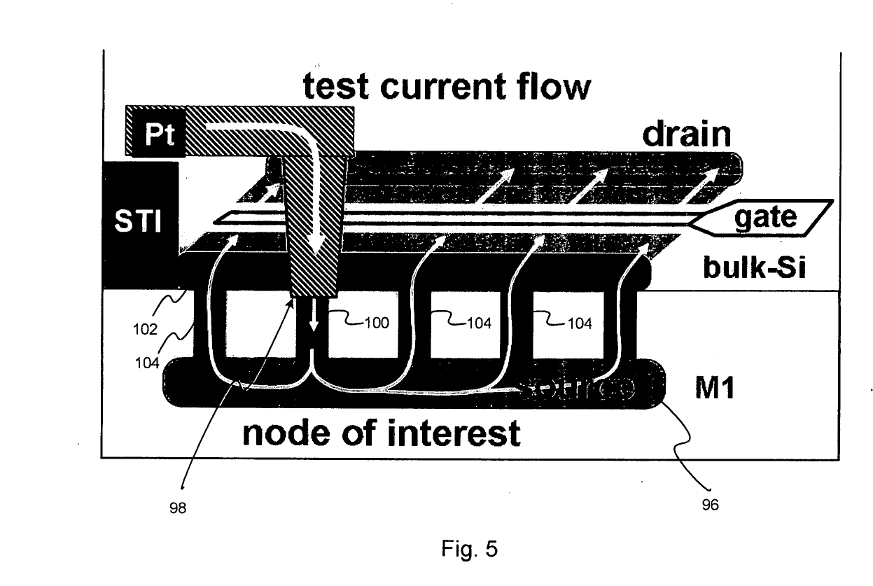

While useful for circuit edit of many IC arrangements, the connection to contact approach may be limited by the number of available contacts in the target device. FIG. 5 illustrates a test current flow in the target device node, in this case the flow through the deposited connector to the contacted tungsten plug 100 to metal line 96 and through the remaining tungsten plugs 104 to the active source area 102 of a FET. The direct connection 98 between the tungsten plug 100 and the active source area 102 may become disconnected or strongly degraded using this method because the former interface from the highly doped diffusion via silicide to the contact is removed during the trench down to the contact level. Thus, other unaffected tungsten plugs 104 may be needed to preserve FET functionality. As a result, the number of tungsten plugs used for the FIB based connection is a trade-off between low ohmic contact and device functionality.

Referring back to FIG. 4, another embodiment of the present invention is illustrated for establishing a conductive contact with a circuit node. In this embodiment, contact to a circuit node is established by making a conductive connection 92 to a silicide region 94 (“CtS” 90). A silicide region may be approximately 20-40 nm thick. Silicides are alloys of silicon and metals, e.g., cobalt silicide, titanium silicide, etc., that are formed during the IC fabrication process. Silicides are generally used to form contacts with active silicon regions because they can reduce parasitic resistance, provide higher thermal stability, provide lower resistivity and provide contact interface protection from electromigration.

In this embodiment, to form a conductive connection to an active node of n-FET 70, a FIB tool may be used to drill an access hole through the P-Well 88 and the underlying n+ active diffusion region 66, endpointing on the silicide region 94 of the active diffusion region 66. Thus, the access hole is opened to the silicide. The FIB tool is then used to deposit a conductive material in the access hole to form an ohmic contact 92 to the silicide without destroying the direct conductive path of the silicide 94 to the surrounding active diffusion region 66. Use of this method allows formation of ohmic connections to every active area, even where no tungsten plugs or other types of contacts are available. A conductive connection to the active diffusion region of a p-FET involves a similar procedure, except that the FIB tool drills an access hole through the N-Well and p+ diffusion region of the p-FET.

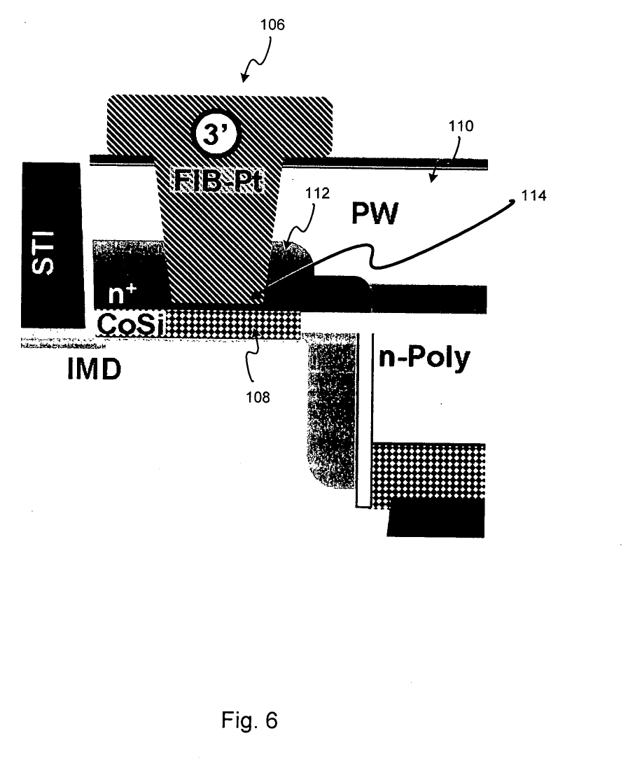

FIG. 6 depicts another way of forming a conductive connection 106 with a silicide region 108 using a FIB tool. In this embodiment, a FIB tool may be used to drill an access hole through the P-Well 110 and most of the way through the n+ diffusion region 112, stopping the milling process approximately 25-50 nm before the silicide layer 108. This results in the formation of a pure ohmic contact 114 without any pre-anneal due to the very high doping level (about 10²⁰ cm⁻³) in this region of the n+ diffusion. The rectifying barrier due to the small band gap in the valence band of the n+ diffusion region can be easily tunneled to produce an ohmic contact. In this embodiment, endpointing may be done by stopping the etch operation after a predetermined time. For example, in one embodiment, a reduced beam current may be used during the etch operation so that it takes about 60 seconds to open an access hole to the silicide layer. By stopping the etch operation after about 50 seconds, the access hole floor will be in the very highly doped region of the n+ diffusion.

As shown in FIG. 6A, an ohmic contact 107 can be established to a silicide layer 115 by depositing a conductive material 109, such as platinum in the access hole 111 as long as the trench floor 113 ends between the active diffusion dopant implant maximum and the silicide layer 115, denoted by valid endpoint margin 117 as shown on the left hand side of FIG. 6A. It should be noted that an ohmic contact can be made to a silicide region of a p+ diffusion in a similar fashion.

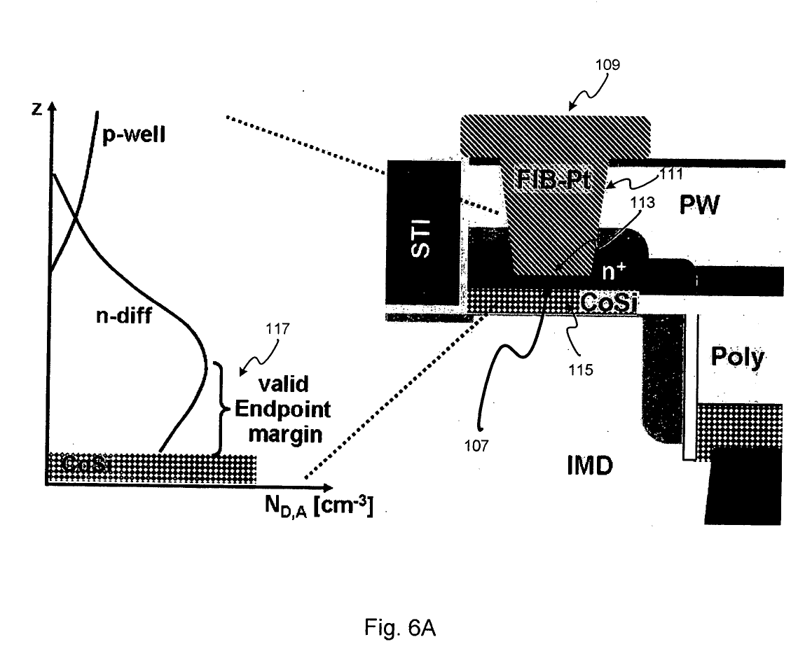

FIG. 7 illustrates a situation where connection to certain active regions 116 of a semiconductor structure 118, marked “possible FIB contacts to Silicide,” may only be accessible by forming a conductive connection to the silicide region because the active node has no contacts. That is, these locations are not connected to any metal that can be used to form a connection with the active region.

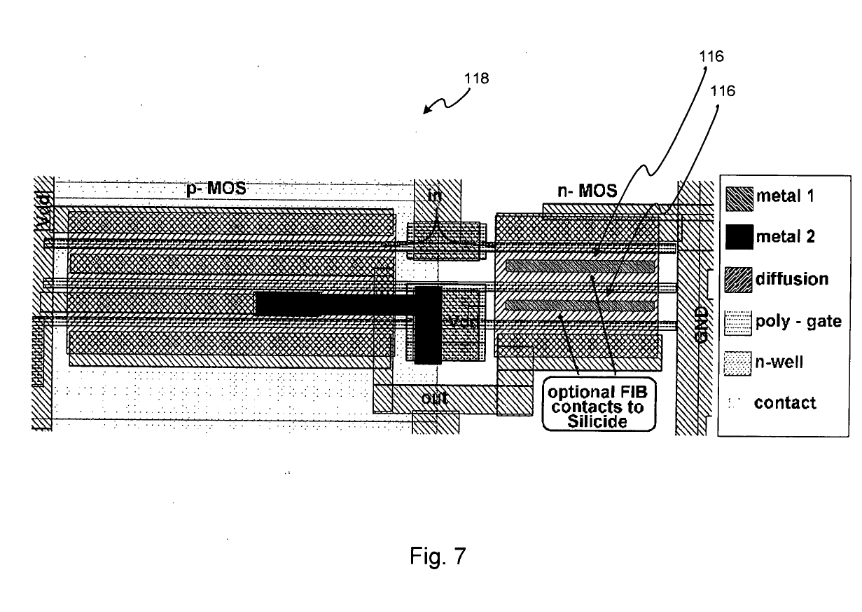

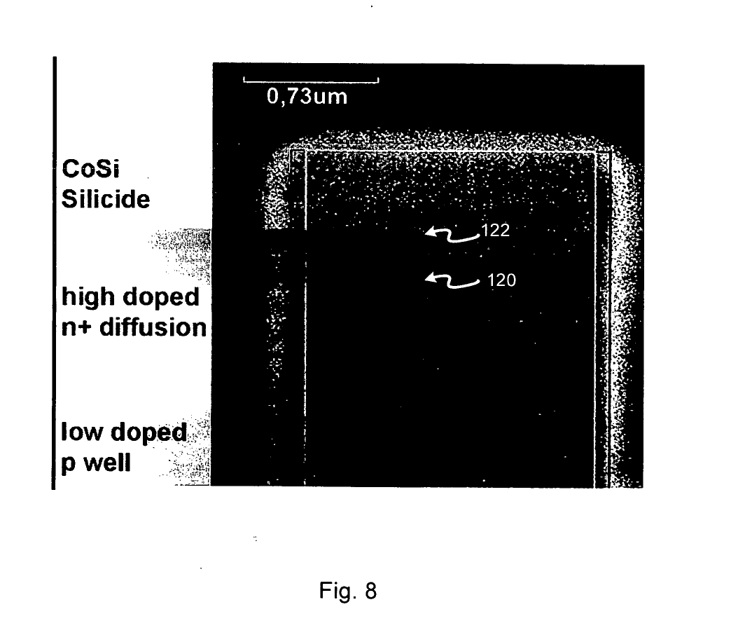

As previously discussed, a FIB tool may be used to mill an access hole through an active diffusion region to the silicide region to form a conductive connection to the active node. The silicide region may be only 20-40 nanometers thick. Thus, in one implementation, the FIB tool is carefully controlled to endpoint on the silicide layer to control the depth of the access hole. Otherwise, the access hole may be milled through the silicide layer. FIG. 8 is an image of an angled cut through a STI surrounded source region. The image illustrates the difference in brightness of the approximately 35 nm thick CoSi layer to the Si material that is observed as a FIB tool makes an angled cut through a low doped p-well and highly doped n+ active source region 120 of a p-FET to the p+ diffusion/CoSi interface 122. This difference in brightness contrast provides a good endpoint signal to halt FIB milling at the CoSi layer as illustrated in FIG. 9. As FIG. 9 illustrates the endpoint detection tool shows a decreasing brightness as the n-well and highly doped p+ diffusion is milled through. The brightness suddenly increases at the CoSi endpoint 124, when the CoSi layer is exposed.

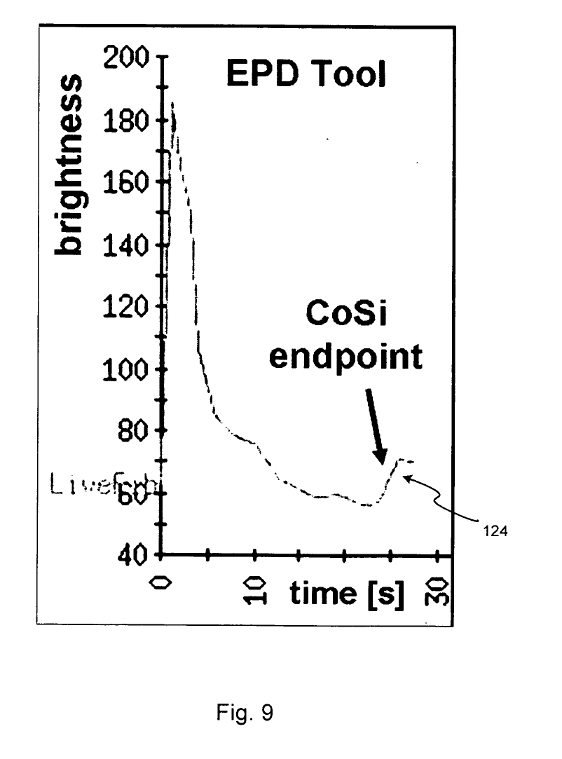

FIG. 10 is a SEM image that depicts a cross-sectional view of a 0.5 μm-wide FIB created contact to silicide 130 through the p-well 132 and n+ diffusion 134 of a n-FET 136. Surrounding the n-FET is a STI region 138. The CtS 130 may be formed by using a FIB to deposit platinum 140 in the access hole to form a contact to the silicide 142. The CtS is located between two Tungsten plugs 144, 146. The tungsten plugs connect the silicide on top of the n+ diffusion to the M1 metal layer 148. The silicide forms a conductive bridge between the deposited conductor, the tungsten plugs and the n+ diffusion. Thus, any form of test signal may be received or transmitted to the n+ diffusion through the deposited conductor and connection to silicide. As FIG. 10 illustrates, a very flat trench floor 150 ending at the CoSi layer 142 was achieved. Shown on the right hand side of FIG. 10 is an enlarged view of a portion of the contact to silicide. A very strong contrast occurs between the CoSi 142 and n+ diffusion 134. The transition region 152 from n+ diffusion 134 to p-well 132 is also clearly visible as is the platinum conductor 140.

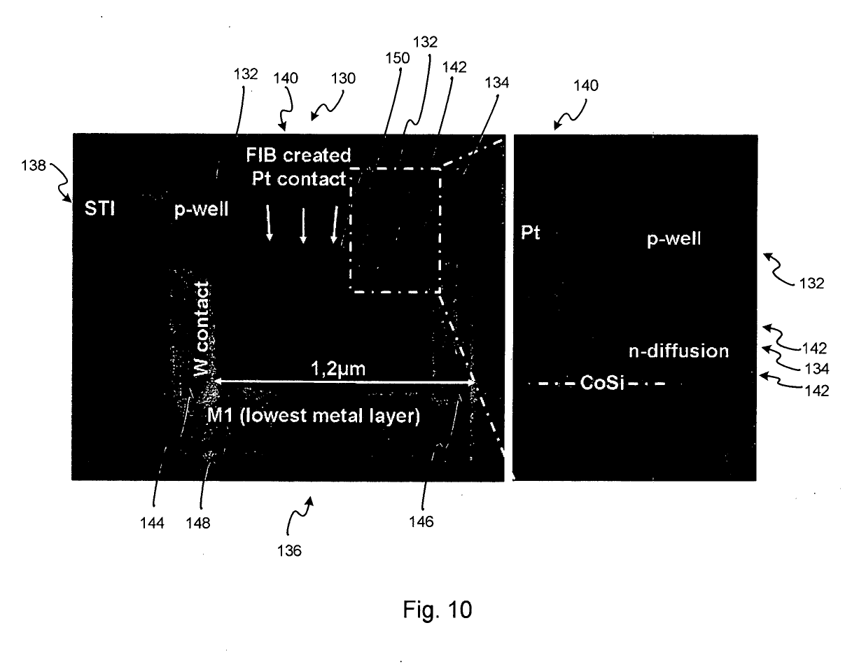

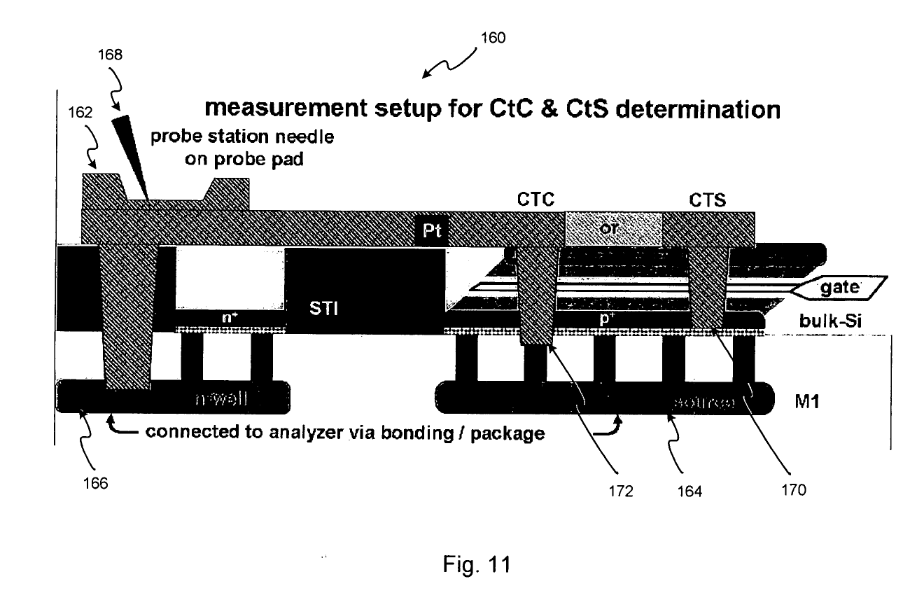

To evaluate the contact properties of the CtS, single FET structures were used. An STI alignment box was opened to allow precise navigation. A 2 μm² contact hole was drilled through the drain diffusion to the silicide and the hole was filled with platinum to form a 2 μm² contact. FIG. 11 depicts the measurement setup 160 used to measure the achieved contact resistance. A probe pad 162 was deposited for each CtS. An additional FIB contact, connecting to the former gate or well input lead, was established to create a low ohmic path to the bond pads of the device package. The supply lead resistance from the DC parameter analyzer via the package lead and the M6 down to M1 metal connections to the drain, source, gate and well were below 100 milliohms and could be neglected. Three measurements were made to plot the CtS I-V curve 174 shown in FIG. 12. Referring back to FIG. 11, the first measurement from the source 164 to the n-well 166 could be performed in the Vacuum chamber after the CtS was established. This measurement monitors the resistance of the series combination of the FIB contact to the M1 well lead and the CtS resistance 170 to the source M1 lead 164.

After the CtS was formed, a second and a third measurement were made outside the Vacuum chamber using a probe station. The second measurement, from the source 164 to the probe pad 162, measured the series combination of the CtS resistance 170 and the probe needle 168 on probe pad 162 resistance. The third measurement, from the n-well 166 to the probe pad 162, measured the series combination of the FIB contact to the M1 well lead and the probe needle 168 on probe pad 162 resistance. The CtS contact resistance was extracted from these three measurements by applying a delta-wye conversion.

FIG. 12 shows the measured CtS I-V curve 174. This demonstrates the formation of an ohmic contact with a resistance times area of less than 50 Ωμm². For a typical CtS contact area of around 0.2 μm², the expected contact resistance would be approximately 250Ω.

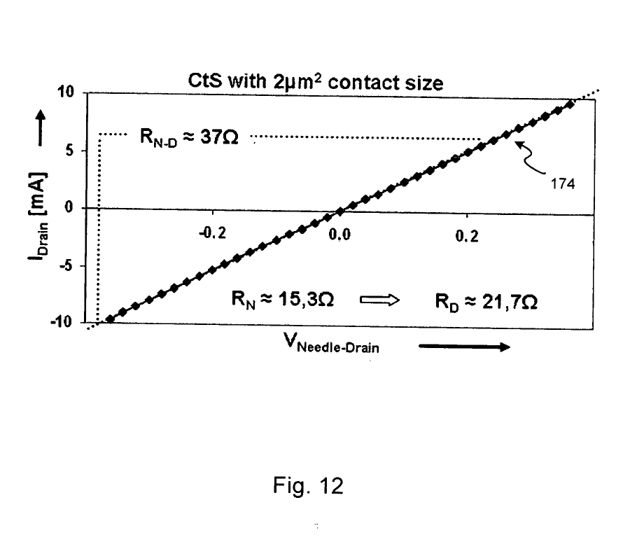

To test the capability of the CtS method, a circuit edit was carried out on a ring oscillator consisting of several 3-way NAND gates. The circuit edit was performed on the 3-gate n-FET portion of one of the 3-way NAND gates and involved opening an alignment window to the STI, milling an access hole to the silicide of one FET of the 3-gate n-FET, filling the access hole with platinum, purposely destroying the two adjacent FETs of the 3-gate n-FET, and then depositing platinum to bypass the destroyed FETs. The ring oscillator 180 is shown on the left side of FIG. 13. A FIB picture of the ring oscillator area 182, opened down to the STI level, is shown on the right side of FIG. 13. The targeted CtS circuit node was chosen in an active diffusion area of the 3-gate n-FET, which is part of one of the 3-way NAND gates of the ring oscillator. Referring back to FIG. 7, the layout of the 3-gate n-FET structure is shown along with the target circuit node.

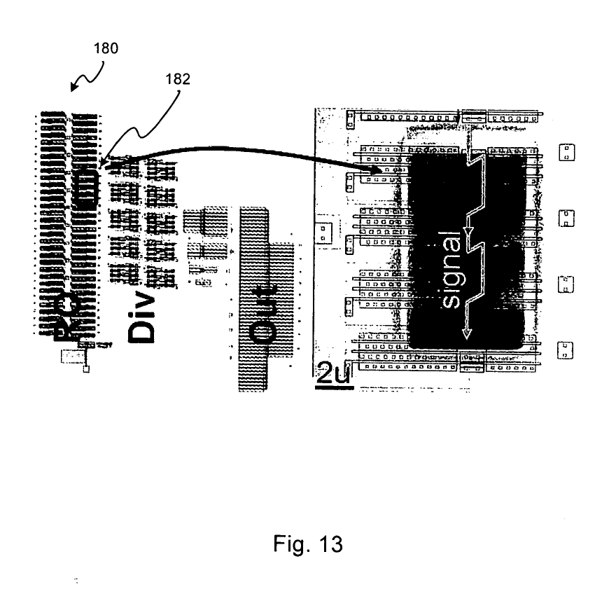

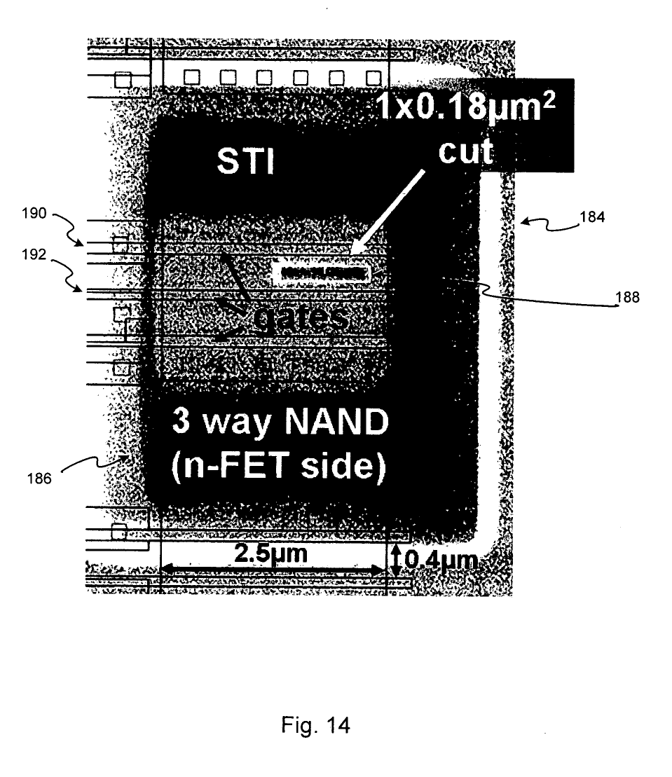

FIGS. 14 and 15 depict various steps of the circuit edit operation performed to test the CtS method. FIG. 14 depicts the STI alignment opening 184 made to reveal the active areas of the 3-gate n-FET 186 in the middle. Next, a 1 μm by 0.18 μm opening 188 down to the CoSi between two polysilicon gates 190, 192, each approximately 110 nm away from the opening, was made.

Referring now to FIG. 15, the CtS opening was then filled with FIB deposited Platinum 200. Then, the two lower transistors were purposely destroyed by milling down in the area marked with a 1 until the polysilicon gates and contacts appeared. Next, the four contacts 202, 204, 206, 208 were sputter cleaned. Finally, a Platinum bar was deposited to connect the CtS 210 to the four contacts 202, 204, 206, 208 of the output node, forming a new conductive connection bypassing the two destroyed transistors.

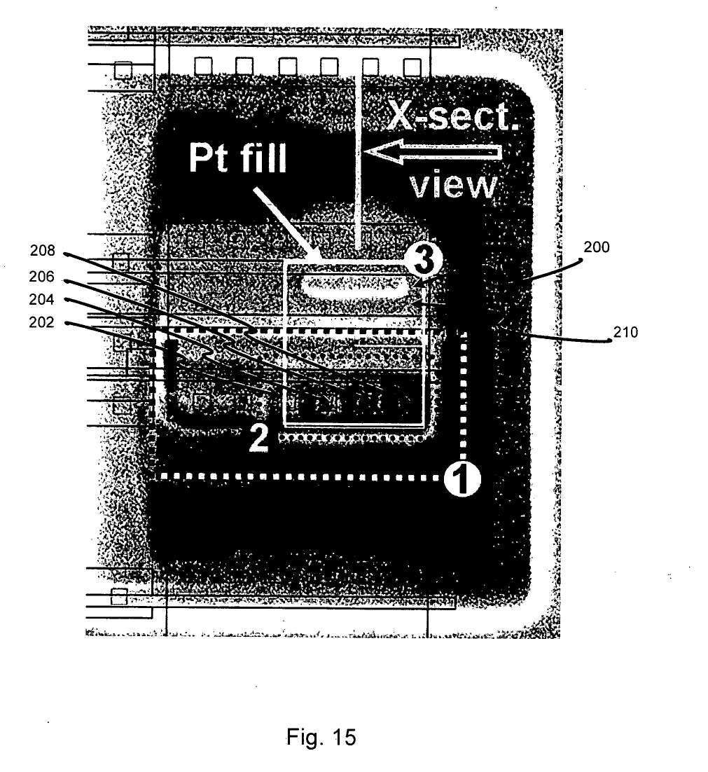

FIG. 16 shows a schematic cross section through the finished CtS circuit edit. Shown are the three gates 220, 222, 224 (of the 3 gate n-FET). Two gates 220, 222 are permanently connected to V_{dd} and the third gate 224 on the right carries the input signal. Also shown are the contact studs 226, 228 to M1 for the output node 230 and to Vₛₛ 232. The area 234, enclosed by a dotted line, indicates the two transistors removed during the circuit edit. Also shown is the Platinum bar 236 connecting the CtS 238 to the output 230 through the contact 226.

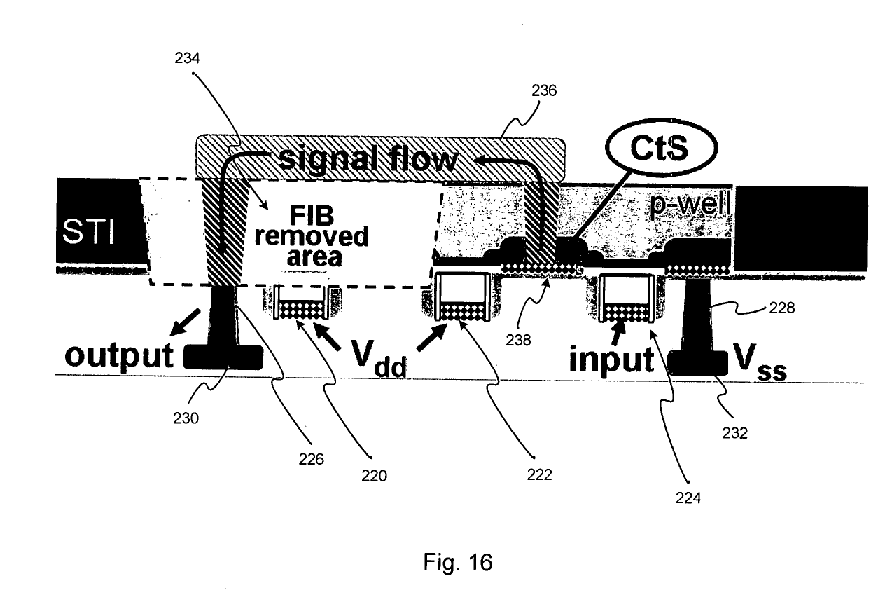

Throughout each step of the circuit edit procedure, the ring oscillator frequency was monitored. The frequency of the ring oscillator is very sensitive to contact resistance. Thus, changes in frequency will indicate a degradation in contact resistance. FIG. 17 shows the ring oscillator frequency 240 during the CtS circuit edit. The ring oscillator frequency remained constant during the STI alignment window opening (labeled STI), the cut to open an access hole to the CoSi layer (labeled CtS), and the Platinum fill of the access hole (labeled PT fill). The ring oscillator frequency dropped to zero when two of the n-FETs were purposely destroyed and disconnected from the oscillator interrupting the signal propagation path (labeled FET destroyed). Finally, the ring oscillator frequency was restored when a new conductive connection around the two destroyed n-FETs was created by the Platinum deposition (area 3 of FIG. 15) to connect the CtS to the output (labeled Pt connection). The ring oscillator frequency recovered to within 1% of its initial value indicating the high quality conductive connection achieved with the CtS method.

Referring back to FIG. 1, the operations of an alternative embodiment of the present invention are now described. First, the substrate is thinned (operation 50) as previously described above. Next, a charged particle beam tool is used to create a trench over the desired circuit edit region (operation 52) as previously described above. Then a FIB tool may be used to mill an access hole through the active node to the contact (operation 58). Finally, a FIB tool may be used to deposit a conductive material in the access hole to form a conductive connection to the contact (operation 60) (“CtC”).

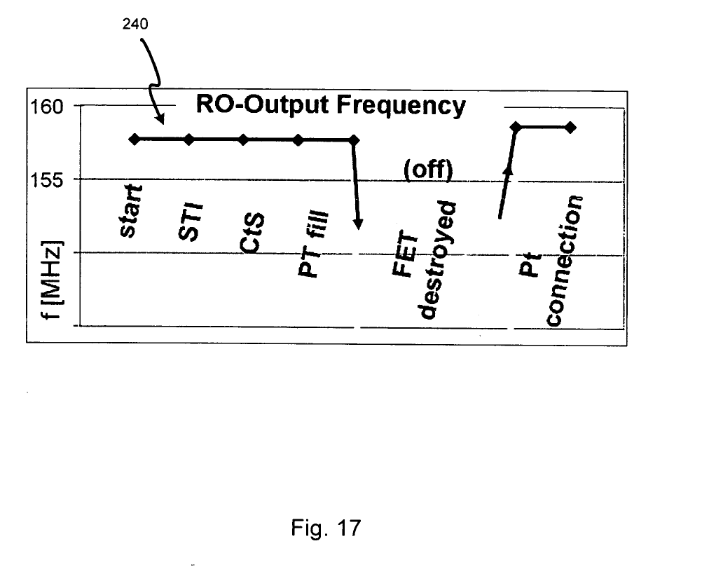

The contact properties of this method were evaluated using single FET structures fabricated in an industrial 120 nm bulk Si process using shallow trench isolation. The test structure, shown in FIG. 18, has a drain 250, source 252, gate 254, and several contacts 256 that form a connection between the active regions and metal layer. After the substrate of the IC has been thinned and a trench opened over the desired circuit edit region, STI alignment boxes 258 were opened at the edges of the drain 250 and source 252. Then alignment markers 260 were placed to allow precise FIB navigation after insulator deposition. Then contact holes 262 were opened to the contacts (two contacts per hole) and filled with platinum to form connection with the contacts. The measurements to determine the CtC resistance were carried out using a measurement technique similar to the one described above to measure the CtS resistance. Referring back to FIG. 11, the CtC resistance 172 was measured rather than the CtS resistance 170. The CtC resistance was determined to be less than 400 Ω per contact. For the experimental structure where two contacts were used in parallel, a resistance of around 180 Ω was obtained.

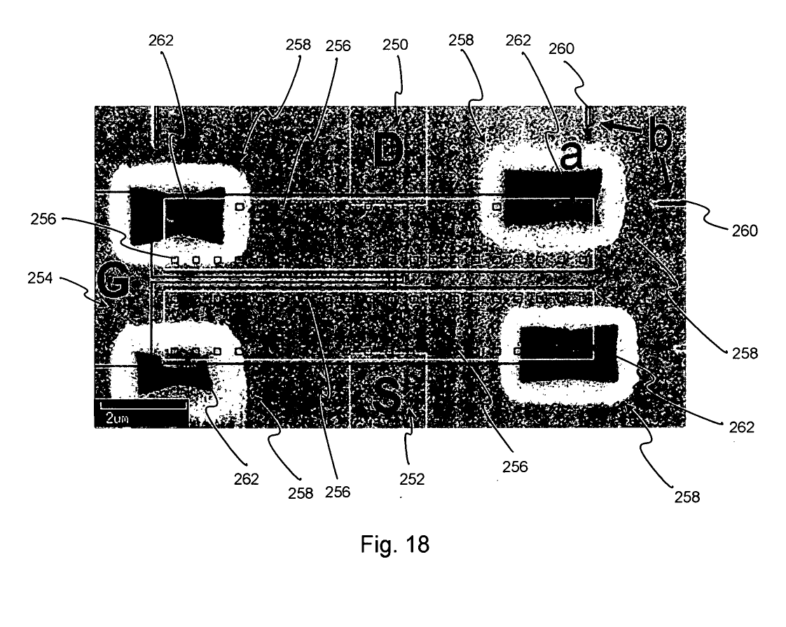

To further test the capability of the CtC method, a circuit edit was carried out on a 170 MHz ring oscillator consisting of NAND gates. The ring oscillator structure is shown in FIG. 13. Referring now to FIG. 19, showing a cross section of the edited ring oscillator, the circuit edit involved thinning the substrate to provide backside circuit edit access to several of the NAND inverters 270, 272, 274, 276 of the ring oscillator, creating a CtC contact 278 to the output 280 of NAND inverter 276, creating a contact to metal (not shown) to the input 282 of NAND inverter 270 located three inverters further along the ring oscillator, depositing a platinum trace 284 to connect the CtC 278 and contact to metal, removing two NAND inverters 272, 274 located between NAND inverter 270 and NAND inverter 276, cutting the platinum trace 284, and reconnecting the platinum trace 284.

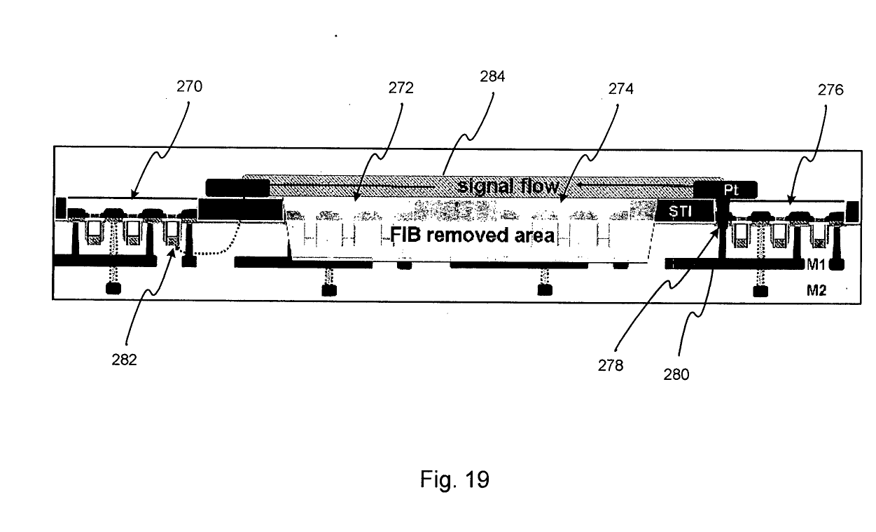

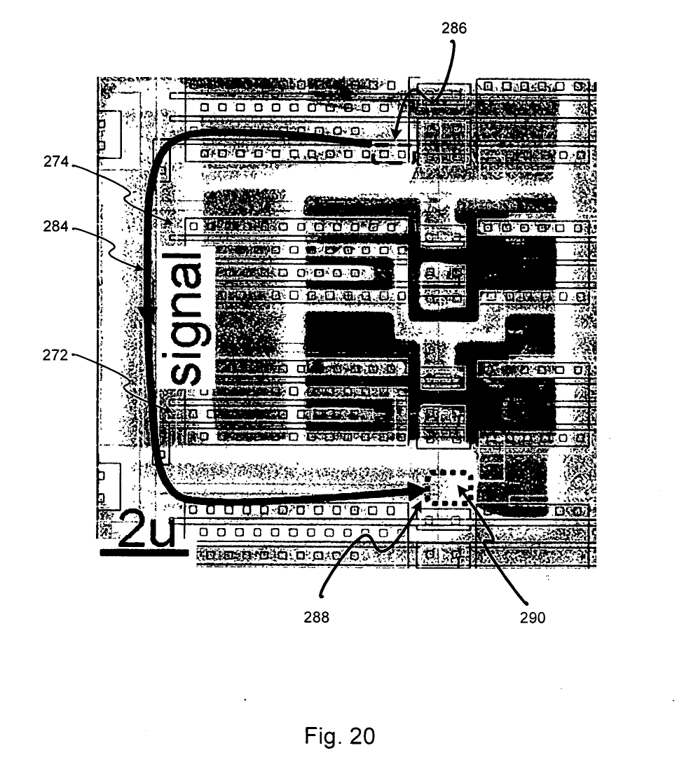

FIG. 20 shows the two NAND inverters 272, 274 to be removed, the contact hole 286 opened to form the CtC with the output 280 of NAND inverter 276 of the ring oscillator ahead of the two NAND inverters 272, 274, the contact hole 288 opened to the metal line 290 connected to the input of NAND inverter 270, and the platinum trace 284 connecting the CtC and contact to metal. FIG. 21 depicts an enlarged view of the access hole for a CtC showing the STI region 292, the active region of the NAND inverter output 294 and two of the contacts forming a connection to the underlying M1 metal.

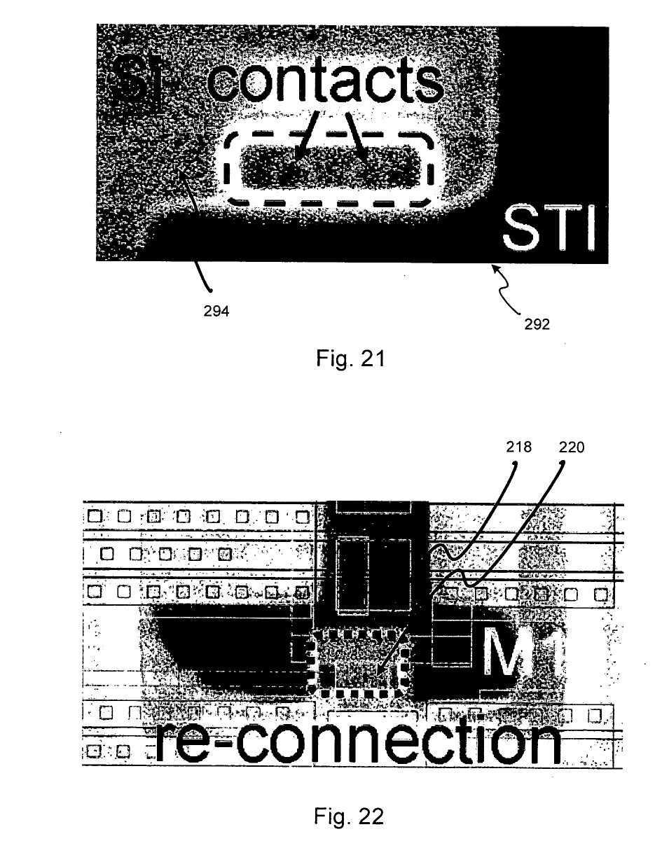

FIG. 22 shows an enlarged view of the connection to metal line of FIG. 20. Depicted is the access hole 288 opened to the metal line 290 which connects to the input 282 of NAND inverter 270.

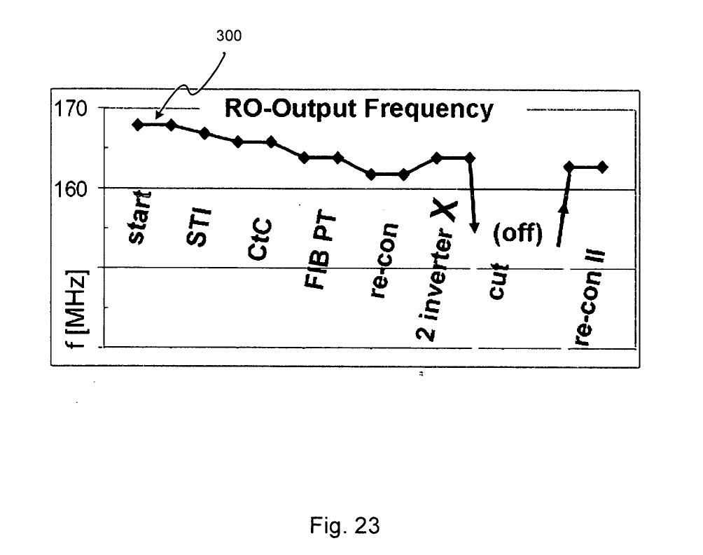

FIG. 23 shows the ring oscillator output frequency 300 during the circuit edit procedure to test the functionality of the contact to contact method performed on the 170 MHz ring oscillator consisting of sixty-five NAND inverters. During the circuit edit, the frequency of the ring oscillator steadily decreased from a starting frequency of 168 MHz (labeled Start) to 162 MHz as the FIB tool opened an alignment window to the STI (labeled STI), milled an access hole to the contact (labeled CtC), filled the access hole with Platinum, and deposited a Platinum trace to connect the contact to contact with the contact to metal (labeled FIB Pt). At this point of the circuit edit, two valid signal paths for the ring oscillator signal exist in the circuit edit region. Next, two inverters were purposely destroyed to remove one of the signal paths (labeled 2 inverter X). Having only the contact to contact signal path, the ring oscillator output frequency increased to 164 MHz. Removal of two of the 65 NAND inverters of the ring oscillator should nominally increase the frequency by about 3%. Even though the increase in ring oscillator output frequency observed was below the 3%, it did show the expected tendency. Next, the FIB created connection was cut causing the ring oscillator frequency to drop to zero interrupting the signal propagation path (labeled cut). Finally, the FIB created connection was restored without any mentionable influence on the ring oscillator circuitry as shown by the ring oscillator output frequency returning to its pre-cut value (labeled re-con 11).

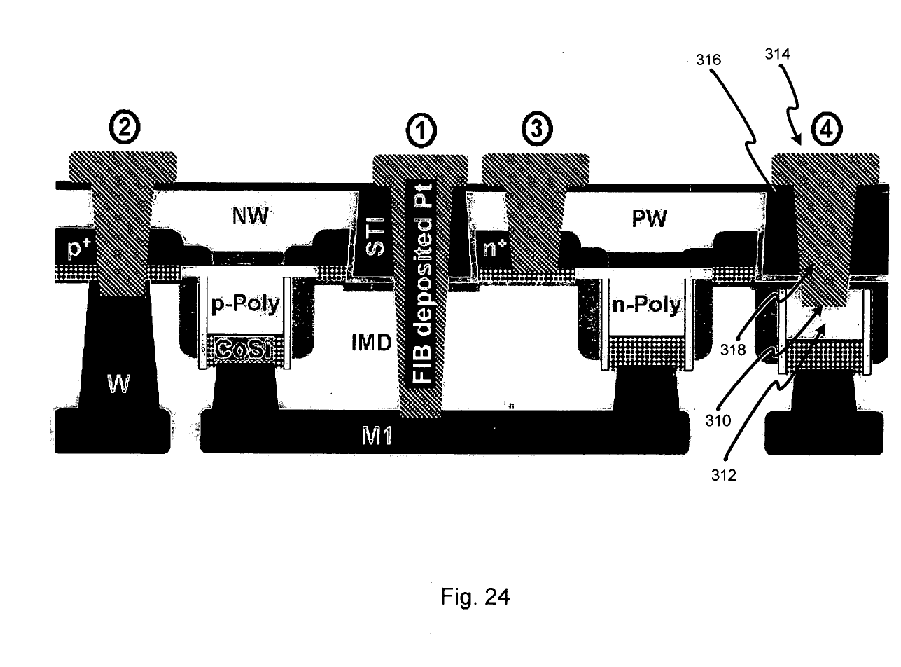

FIG. 24 illustrates another embodiment of the present invention for establishing a conductive contact with a circuit node. In this embodiment, contact to a circuit node is established by making a conductive connection 310 to a polysilicon gate contact area 312 (“CtP” 314) or other polysilicon structure such as but not limited to a polysilicon resistor or polysilicon interconnect over an isolation oxide such as STI. Suitable polysilicon gate contact areas include the supply or input contact area of a gate structure but not the polysilicon above active silicon and gate oxide. Contact can be made to polysilicon structures fabricated on STI where the polysilicon structure is not above active/diffusion areas.

A polysilicon gate contact area 312 is typically 50 to 100 nm thick. To form a conductive connection with the polysilicon gate contact area 312, the substrate is first thinned as previously described above. Next, a charged particle beam tool is used to create a trench over the desired circuit edit region as previously described above. Then a FIB tool may be used to drill an access hole through a shallow trench isolation region 316, endpointing on the polysilicon gate contact area 312. In one embodiment, the access hole may be milled with a FIB using an unassisted etch and a beam current of approximately 4 pA/μm². The FIB tool is then used to deposit a conductive material 318 such as platinum in the access hole to form an ohmic contact 310 to the polysilicon gate contact area 312 without destroying the conductive path of the polysilicon gate contact area to the polysilicon gate.

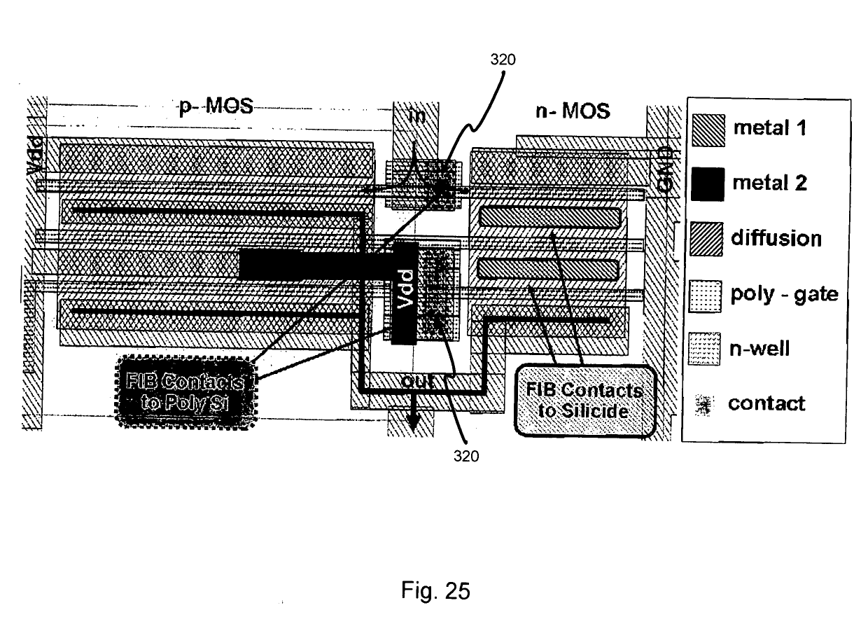

FIG. 25 illustrates possible FIB contacts 320 to polysilicon gate contact areas of a three way NAND gate. The CtP method, along with the previously described CtS method enable contact to all three terminals of a discrete device during circuit edit operations.

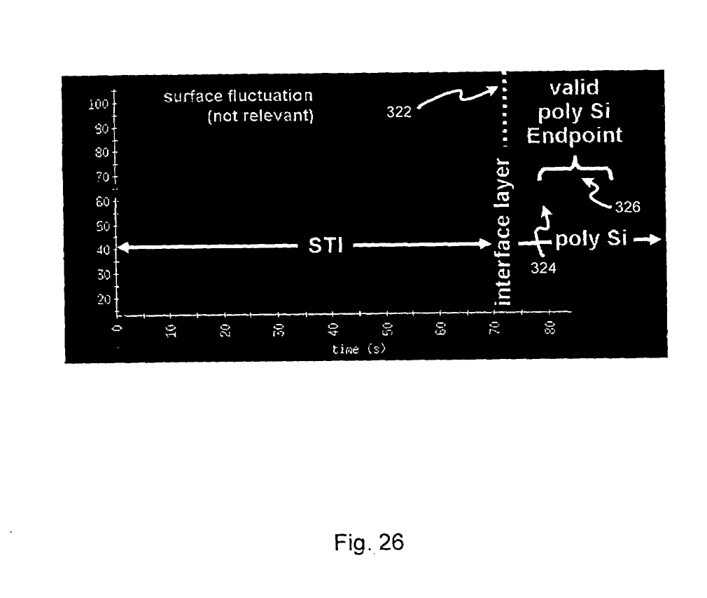

As FIG. 26 illustrates, the endpoint detection tool brightness fluctuates during FIB milling of the STI layer. A peak in brightness 322 occurs at the STI/polysilicon interface. The brightness suddenly decreases at the polysilicon endpoint 324, when the polysilicon gate contact area is exposed. Because the polysilicon gate contact area generally is around 50 to 100 nm thick, the FIB milling of the access hole can be halted when the trench floor reaches the polysilicon layer as shown by the valid polysilicon endpoint 326.

The apparatus and method described above for creating conductive contacts to a circuit node of interest may be accomplished at nominal sample temperatures in the vacuum of the focused ion beam tool work chamber (room ambient temperature approximately 20-25 degrees Celsius). That is, no provision is necessary for elevated or reduced temperature control of the focused ion beam tool work chamber.

Various aspects of the present invention, whether alone or in combination with other aspects of the invention, may be implemented in C++ code running on a computing platform operating in a LSB 2.0 Linux environment. However, aspects of the invention provided herein may be implemented in other programming languages adapted to operate in other operating system environments. Further, methodologies may be implemented in any type of computing platform, including but not limited to, personal computers, mini-computers, main-frames, workstations, networked or distributed computing environments, computer platforms separate, integral to, or in communication with charged particle tools, and the like. Further, aspects of the present invention may be implemented in machine readable code provided in any memory medium, whether removable or integral to the computing platform, such as a hard disc, optical read and/or write storage mediums, RAM, ROM, and the like. Moreover, machine readable code, or portions thereof, may be transmitted over a wired or wireless network.

Although various representative embodiments of this invention have been described above with a certain degree of particularity, those skilled in the art could make numerous alterations to the disclosed embodiments without departing from the spirit or scope of the inventive subject matter set forth in the specification and claims. In methodologies directly or indirectly set forth herein, various steps and operations are described in one possible order of operation, but those skilled in the art will recognize that steps and operations may be rearranged, replaced, or eliminated without necessarily departing from the spirit and scope of the present invention. It is intended that all matter contained in the above description or shown in the accompanying drawings shall be interpreted as illustrative only and not limiting. Changes in detail or structure may be made without departing from the spirit of the invention as defined in the appended claims.

What is claimed is:

1. A method for performing a circuit edit to form a conductive connection with an active node of a semiconductor structure comprising:
opening a contact hole through an active diffusion region to a silicide layer associated with the active diffusion region; and
depositing a conductive material in the contact hole to form a conductive connection to the silicide layer.

2. The method of claim 1 further comprising:
opening an alignment window through a diffusion well to an isolation region associated with the active diffusion region; and
locating the contact hole through the active diffusion region using the alignment window.

3. The method of claim 1 further comprising:
endpointing on the silicide layer to halt the operation of opening a contact hole through the active diffusion region.

4. The method of claim 1 further comprising:
halting the operation of opening a contact hole through the active diffusion region in a highly doped area of the active diffusion region adjacent the silicide layer.

5. The method of claim 4 wherein the active diffusion region has a dopant profile maximum and the highly doped area comprises a region extending from the dopant profile maximum to the silicide layer.

6. The method of claim 1 further comprising:
halting the operation of opening a contact hole through the active diffusion region approximately 25 to 50 nm before the silicide layer.

7. The method of claim 2 wherein the isolation region comprises a shallow trench isolation.

8. The method of claim 2 wherein the diffusion well is selected from the group consisting of a n-well and a p-well.

9. The method of claim 1 wherein the active diffusion region comprises a n+ diffusion of a n-FET.

10. The method of claim 1 wherein the active diffusion region comprises a p+ diffusion of a p-FET.

11. The method of claim 1 wherein the conductive material is platinum.

12. The method of claim 1 wherein the silicide is CoSi.

13. The method of claim 1 further comprising:
creating an access hole to a contact through an active diffusion region; and
depositing a conductive material in the access hole to form a conductive contact with the contact.

14. The method of claim 13 further comprising depositing a conductive material from the conductive contact with the contact to the conductive connection with the silicide.

15. The method of claim 13 wherein the contact is a tungsten plug.

16. The method of claim 1 wherein the contact hole has a low aspect ratio.

17. The method of claim 1 further comprising:
placing an alignment marker to facilitate navigation of a particle beam tool; and
depositing a thin insulating layer over the diffusion well.

18. The method of claim 1 wherein the conductive connection with the silicide layer forms an ohmic contact with a resistance times area of approximately 50 ohms μm².

19. A charged particle beam tool configured to execute the method of claim 1.

20. The method of claim 19 wherein the charged particle beam tool is a focused ion beam tool.

21. A computer-readable medium containing computer-executable instructions which, when executed, perform the method of claim 1.

22. A method for performing a circuit edit to form a conductive connection with an active node of a semiconductor structure comprising:
opening a contact hole through an active diffusion region to a contact associated with the active diffusion region; and
depositing a conductive material in the contact hole to form a conductive connection to the contact.

23. The method of claim 22 further comprising opening an alignment window through a diffusion well to an isolation region associated with the active diffusion region, the alignment window used to locate the contact hole through the active diffusion region.

24. The method of claim 23 wherein the isolation region comprises a shallow trench isolation.

25. The method of claim 23 wherein the diffusion well is selected from the group consisting of a n-well and a p-well.

26. The method of claim 22 wherein the active diffusion region comprises a n+ diffusion of a n-FET.

27. The method of claim 22 wherein the active diffusion region comprises a p+ diffusion of a p-FET.

28. The method of claim 22 wherein the conductive material is platinum.

29. The method of claim 22 wherein the contact is a tungsten plug.

30. The method of claim 22 wherein the contact hole has a low aspect ratio.

31. The method of claim 22 further comprising:
placing an alignment marker to facilitate navigation of a particle beam tool; and
depositing a thin insulating layer over the diffusion well.

32. A charged particle beam tool configured to execute the method of claim 22.

33. The method of claim 32 wherein the charged particle beam tool is a focused ion beam tool.

34. A computer-readable medium containing computer-executable instructions which, when executed, perform the method of claim 22.

35. A method for performing a circuit edit to form a conductive connection with an active node of a semiconductor structure comprising:
opening a contact hole through a shallow trench isolation region to a polysilicon structure; and
depositing a conductive material in the contact hole to form a conductive connection to the polysilicon structure.

36. The method of claim 35 wherein the polysilicon structure is selected from the group consisting of a polysilicon resistor, a polysilicon interconnect, and a polysilicon gate contact area.

37. The method of claim 36 wherein the semiconductor structure is a FET, the FET having an active diffusion area, a gate oxide area, and a polysilicon gate, and the polysilicon gate contact area comprises a portion of the polysilicon gate outside the active diffusion area and the gate oxide area.

38. The method of claim 35 wherein the conductive material is platinum.

39. A charged particle beam tool configured to execute the method of claim 35.

40. The method of claim 39 wherein the charged particle beam tool is a focused ion beam tool.

41. A computer readable medium containing computer-executable instructions which, when executed, perform the method of claim 35.

42. The method of claim 20, 33, or 40 wherein the circuit edit on the semiconductor structure is accomplished at nominal sample temperatures in the vacuum of the focused ion beam tool work chamber (room ambient temperature approximately 20 to 25 degrees Celsius).
